(19) United States
(12) Patent Application Publication
(10) Pub. No.: US 2016/0179135 A1
(43) Pub. Date: Jun. 23, 2016

(54) ELECTRONIC APPARATUS HAVING TWO CIRCUIT BOARDS ELECTRICALLY CONNECTED TO EACH OTHER

(71) Applicant: KABUSHIKI KAISHA TOSHIBA, Tokyo (JP)

(72) Inventor: Kengo KUMAGAI, Yokohama Kanagawa (JP)

(21) Appl. No.: 14/834,162

(22) Filed: Aug. 24, 2015

(30) Foreign Application Priority Data
Dec. 22, 2014 (JP) 2014-259506

(51) Int. Cl. G06F 1/16; G06F 1/18; H05K 1/18

(52) U.S. Cl. CPC G06F 1/1613; H05K 1/181; G06F 1/183; H05K 2201/10159

(57) ABSTRACT

An electronic apparatus includes a housing, a first circuit board including a first engaging portion configured to fix the first circuit board to the housing, and a first terminal, and a second circuit board including a second engaging portion configured to fix the second circuit board to the housing, and a second terminal electrically connected to the first terminal.

### CROSS-REFERENCE TO RELATED APPLICATION

This application is based upon and claims the benefit of priority from Japanese Patent Application No. 2014-259506, filed Dec. 22, 2014, the entire contents of which are incorporated herein by reference.

### FIELD

Embodiments described herein relate generally to an electronic apparatus, in particular an electronic apparatus having two circuit boards electrically connected to each other.

### BACKGROUND

An electronic apparatus includes a semiconductor device having a controller and a semiconductor memory.

### DESCRIPTION OF THE DRAWINGS

FIG. 1 illustrates a system configuration of a semiconductor device according to a first embodiment.

FIG. 2 is a perspective view of a host device containing the semiconductor device therein.

FIG. 3 is a partial cross-sectional view of a tablet type portable computer.

FIG. 4 illustrates the semiconductor device according to the first embodiment.

FIG. 5 is a cross-sectional view of a NAND memory and a controller in the semiconductor device.

FIG. 6 is a block diagram of a system configuration of the controller.

FIG. 7 is a perspective view of a connector unit in the semiconductor device according to one example.

FIG. 8 is a perspective view of a connector unit in the semiconductor device according to another example.

FIG. 9 is a top cross-sectional view of the connector unit.

FIG. 10 illustrates a main board of the host device.

FIG. 11 is a perspective view of a connector unit.

FIG. 12 illustrates a semiconductor device according to a second embodiment.

FIG. 13 is a side cross-sectional view of the semiconductor device and a main board according to the second embodiment.

FIG. 14 is a side view of a semiconductor device and a main board according to a third embodiment.

FIG. 15 is a cross-sectional view illustrating an example of a connector unit, an interface unit, and a cover, according to the third embodiment.

FIG. 16 is a cross-sectional view illustrating another example of the connector unit, the interface unit, and the cover, according to the third embodiment.

FIG. 17 is a perspective view of a connector unit, an interface unit according to a fourth embodiment.

FIG. 18 is a partial cross-sectional view of a tablet type portable computer according to a fifth embodiment.

FIG. 19 illustrates a main board according to a sixth embodiment.

FIG. 20 illustrates a semiconductor device and the main board according to the sixth embodiment.

### DETAILED DESCRIPTION

One embodiment provides a thin electronic apparatus.

In general, according to an embodiment, an electronic apparatus includes a housing, a first circuit board including a first engaging portion configured to fix the first circuit board to the housing, and a first terminal, and a second circuit board including a second engaging portion configured to fix the second circuit board to the housing, and a second terminal electrically connected to the first terminal.

Hereinafter, embodiments will be described with reference to the drawings.

In the disclosure, a plurality of expressions is used for some elements. The expressions are merely examples and may be expressed using different expressions. In addition, elements for which a plurality of expressions is not used may also be expressed using different expressions.

In addition, the drawings are schematic, and a relationship between a thickness and a planar dimension, a ratio of the thicknesses of each layer, or the like may be different from actual ones. In addition, a section in which a relationship or a ratio between dimensions is different from each other in the drawings may be included.

### First Embodiment

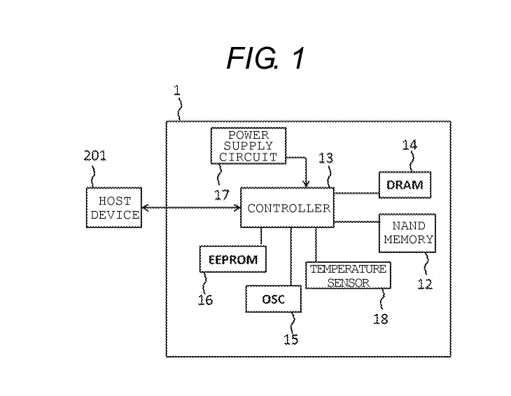

FIG. 1 illustrates a system configuration of a semiconductor device 1 according to a first embodiment. The semiconductor device 1 is an example a “semiconductor module” and a “semiconductor memory device.” The semiconductor device 1 according to the present embodiment is, for example, a solid state drive (SSD), but is not limited thereto.

As illustrated in FIG. 1, the semiconductor device 1 according to the present embodiment is connected to a portable computer, which is an example of an electronic apparatus, or to a host device 201 (hereinafter, referred to as a host) such as a CPU core, via a memory connection interface such as an interface according to the standard, such as serial advanced technology attachment (SATA) or peripheral component interconnect express (PCIe), and functions as an external memory of the host device 201. In addition, an interface 2 may be one according to another standard.

The semiconductor device 1 receives an electric power from the host device 201 via an interface. A CPU of a personal computer, a CPU of an imaging device, such as a still camera or a video camera, or the like may be used as the host device 201. In addition, the semiconductor device 1 may perform data communication with a debug device via a communication interface such as an RS232C interface (RS232C I/F). In addition, the semiconductor device 1 may be used as a storage device of an electronic apparatus, such as a notebook type portable computer, a tablet terminal, or a detachable notebook personal computer (PC).

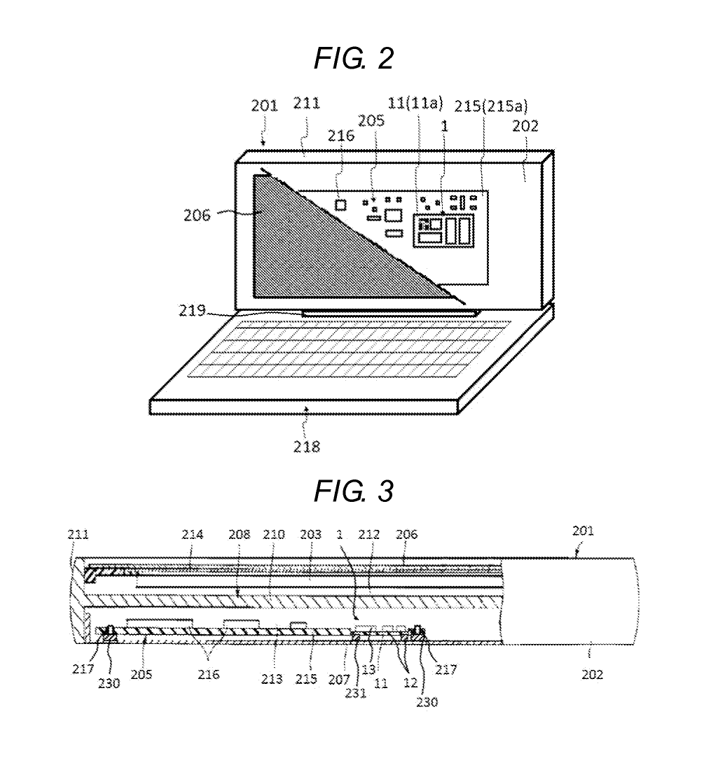

FIG. 2 is a perspective view of the semiconductor device 1 disposed in a detachable notebook PC in which a display device side thereof is detachable from an input device side thereof. In addition, FIG. 3 is a cross-sectional view of a display device side of the detachable notebook PC illustrated in FIG. 2, that is, a tablet type portable computer 201. In addition, in the detachable notebook PC, the tablet type portable computer 201 and an input device 218 are connected to each other through a connection unit 219. As illustrated in FIG. 2, the semiconductor device 1 is disposed in the tablet type portable computer 201 of the detachable notebook PC. For this reason, even if the input device side and the display device side in the detachable notebook PC are separated from each other, only the display device side may function as the tablet type portable computer 201. In addition, the tablet type portable computer 201 is an example of an electronic apparatus, and, for example, has a size that a user may use the tablet type portable computer 201 by holding it in his or her hand. In this case, the tablet type portable computer 201 functions as a host device of the semiconductor device 1.

The tablet type portable computer 201 includes a housing 202, a display module 203, the semiconductor device 1, and a main board 205. The housing 202 includes a protection plate 206, a base 207, and a frame 208. The protection plate 206 is a square plate made of glass or plastic, and configures a surface of the housing 202. The base 207 is made of a metal, such as an aluminum alloy or a magnesium alloy, and configures the bottom of the housing 202.

The frame 208 is provided between the protection plate 206 and the base 207. The frame 208 is made of metal, such as an aluminum alloy or a magnesium alloy, and has a mounting section 210 and a bumper section 211 which are configured as one piece. The mounting section 210 is disposed between the protection plate 206 and the base 207. According to the present embodiment, the mounting section 210 defines a first mounting space 212 between the mounting section 210 and the protection plate 206, and defines a second mounting space 213 between the mounting section 210 and the base 207.

The bumper section 211 is formed in an outer circumference portion of the mounting section 210 and integrally with the mounting section 210, and continuously surrounds the first mounting space 212 and the mounting space 213 in a circumferential direction. Furthermore, the bumper section 211 extends in a thickness direction of the housing 202 so as to be spanned between the outer circumference portion of the protection plate 206 and the outer circumference portion of the base 207, and configures the outer circumference surface of the housing 202.

The display module 203 is mounted in the first mounting space 212 of the housing 202. The display module 203 is covered with the protection plate 206, and a touch panel 214, which has a handwriting input function, is disposed between the protection plate 206 and the display module 203. The touch panel 214 adheres to the rear surface of the protection plate 206.

In addition, as illustrated in FIG. 3, a plurality of first fixing sections 230 and a plurality of second fixing sections 231 are provided in the second mounting space in the housing 202. The first fixing sections 230 and the second fixing sections 231 are, for example, protrusions having screw holes, the main board 205 is fixed to the plurality of first fixing sections 230 by screws, and the semiconductor device 1 is fixed to the plurality of second fixing sections 231 by screws.

In addition, by aligning the heights of the protrusion sections of the first fixing sections 230 and the second fixing sections 231, a substrate 11 of the semiconductor device 1 and a substrate 215 of the main board 205 are positioned on the substantially same plane.

The semiconductor device 1 is accommodated in the second mounting space 213 of the housing 202 together with the main board 205. The semiconductor device 1 includes the substrate 11, a NAND memory 12, a controller 13, and an electronic component such as a DRAM 14.

The substrate 11 is, for example, a printed wiring plate, and includes a first surface 11a (mounting surface) on which patterned conductors (not illustrated) are formed. Circuit components are disposed on the mounting surface 11a of the substrate 11 and are soldered to the conductor patterns.

The main board 205 includes the substrate 215 and a plurality of circuit components 216 such as semiconductor packages, and is fixed to the first fixing section 230 of the housing 202 by screws that pass through the screw holes 217.

The substrate 215 includes a first surface (mounting surface) 215a on which a plurality of patterned conductors (not illustrated) is formed. The circuit components 216 are disposed on the mounting surface 215a of the substrate 215 and are soldered to conductor patterns.

The semiconductor device 1 according to the present embodiment is a single side mounting device in which circuit components such as the NAND memory 12 are disposed only on the mounting surface 11a. Thus, circuit components that protrude from an external surface are not disposed on a second surface 11b that is opposite to the first surface 11a. For this reason, as illustrated in FIG. 3, the semiconductor device 1 may be disposed in the tablet type portable computer 201 that is required to have a thin shape.

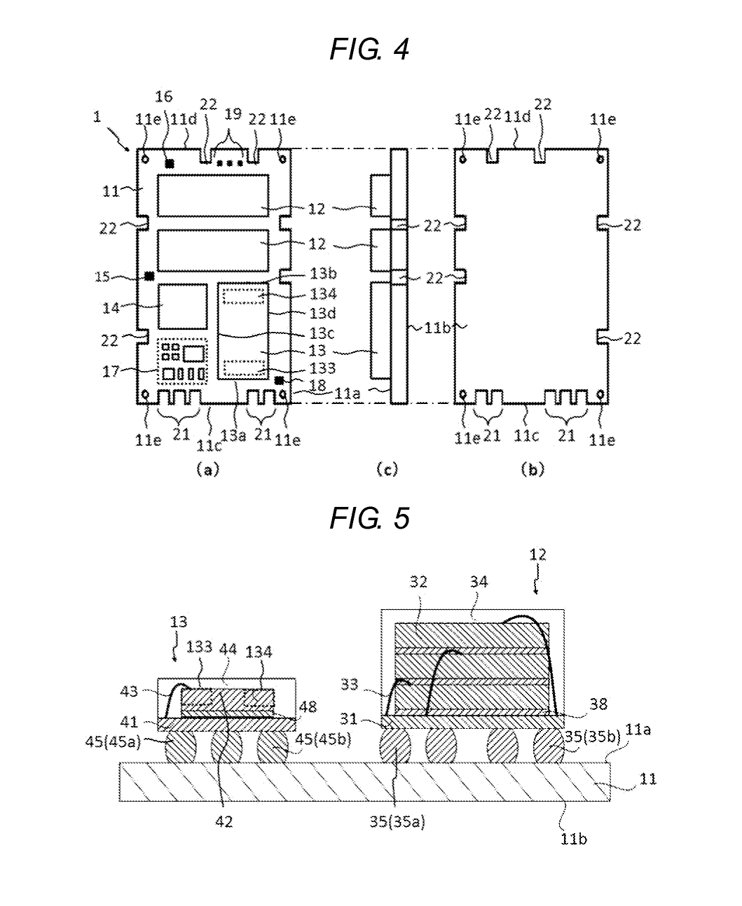

FIG. 4 is a specific example of the semiconductor device 1. In FIG. 4, (a) is a plan view, (b) is a bottom surface view, and (c) is a side surface view of the semiconductor device 1. The semiconductor device 1 includes the substrate 11, the NAND type flash memory (hereinafter, referred to as a NAND memory) 12, which is used as a nonvolatile semiconductor memory element, the controller 13, the dynamic random access memory (DRAM) 14, which is a volatile semiconductor memory element that may perform a faster storing operation than the NAND memory 12, an oscillator 15 (OSC), an electrically erasable and programmable ROM (EEPROM) 16, a power supply circuit 17, a temperature sensor 18, and electronic components 19, such as a resistor and a capacitor.

In addition, the NAND memory 12 and the controller 13 according to the present embodiment are disposed as a semiconductor package. For example, a semiconductor package of the NAND memory 12 is a module of a system in package (SiP) type, and a plurality of semiconductor chips is sealed in one package. The controller 13 controls an operation of the NAND memory 12.

The substrate 11 is a circuit substrate of a substantially rectangular shape and formed of a material such as glass epoxy resin, and defines the outer dimension of the semiconductor device 1. The substrate 11 includes a first surface 11a and a second surface 11b opposite to the first surface 11a. In the present disclosure, a surface other than the first surface 11a and the second surface 11b among the surfaces that configure the substrate 11 is defined as a “side surface.” The first surface 11a is a component disposing surface on which the NAND memory 12, the controller 13, the DRAM 14, the oscillator 15, the EEPROM 16, the power supply component 17, the temperature sensor 18, another electronic component 19, such as a resistor and a capacitor, and the like are disposed.

The substrate 11 according to the present embodiment is, for example, a single surface mounting substrate, and all components that configure the semiconductor device 1 are disposed on the first surface 11a. Meanwhile, the second surface 11b is a non-component mounting surface on which components are not disposed. By doing this, as described above, the semiconductor device 1 according to the present embodiment may be thinner, compared to a case in which substrate-mounted components that protrude from the surface are disposed on both surfaces of the substrate 11.

Here, a single-surface mounting is employed, but another component or function may be mounted on the second surface 11b of the substrate 11 according to the present embodiment. For example, in order to easily perform performance verification of a product, a pad for test may be provided on the second surface. In this case, restriction for a high density design for providing a pad in a narrow region of the first surface 11a, adjustment of a position of other components on the first surface 11a, or the like is not required, and thus the degree of design freedom of pad mounting is improved. Then, a pad electrode for test may be provided on the second surface 11b that is opposite to the first surface 11a, whereby it is possible to shorten a wiring length for routing, and to avoid electrical loss.

The substrate 11 has a substantially rectangular shape as described above, and includes a first edge 11c that is positioned along a lateral direction and a second edge 11d that is positioned on a side opposite to the first edge 11c. The first edge 11c includes a connector section 21 (substrate interface section, terminal section, connection section). The connector section 21 includes a plurality of concave curve sections 21a (metal terminals) that is used as, for example, connection terminals. The connector section 21 is electrically connected to the host device 201. The connector section 21 transmits and receives signals (control signal and data signal) to and from the host device 201.

The connector section 21 according to the present embodiment is an interface according to the standard of, for example, PCI Express (PCIe). That is, a high speed signal (high speed differential signal) according to the standard of the PCIe is transferred between the connector section 21 and the host device 201. The connector section 21 may be one according to, for example, other standards. The semiconductor device 1 receives an electric power from the host device 201 via the connector section 21.

The power supply circuit 17 is, for example, a DC-DC converter, and generates a predetermined voltage necessary for the semiconductor package 12 or the like using electric power received from the host device 201. In addition, it is preferable that the power supply circuit 17 is provided in the vicinity of the connector section 21, in order to reduce loss of the electric power from the host device 201.

The controller 13 controls an operation of the NAND memory 12. That is, the controller 13 controls writing, reading, and erasing of data on the NAND memory 12.

The DRAM 14 is an example of a volatile memory, and is used for storage of management information of the semiconductor memory 32, cache of data, or the like.

The oscillator 15 supplies the controller 13 with an operation signal with a predetermined frequency. The EEPROM 16 stores a control program or the like as fixed information. The temperature sensor 18 detects temperature of the semiconductor device 1 and notifies the controller 13 of the detected temperature.

FIG. 5 illustrates a cross section that discloses a semiconductor package, which is used as the NAND memory 12, and a semiconductor package, which is used as the controller 13, according to the present embodiment. The controller 13 includes a package substrate 41, a controller chip 42, a bonding wire 43, a sealing section (mold material) 44, and a plurality of solder balls 45. The NAND memory 12 includes a package substrate 31, a plurality of semiconductor memories 32, a bonding wire 33, a sealing section (mold material) 34, and a plurality of solder balls 35.

The substrate 11 is, for example, a wiring substrate with multiple layers as described above, includes a power supply layer (not illustrated), a ground layer, and internal wires, and electrically connects the controller chip 42 to the plurality of semiconductor memories 32 via the bonding wires 33 and 43, the plurality of solder balls 35 and 45, and the like.

As illustrated in FIG. 5, the plurality of solder balls 35 and 45 is provided on the package substrates 31 and 41. For example, the plurality of solder balls 35 and 45 is arranged in a lattice pattern on a second surface 31b of the package substrate 31. It is not necessary for the plurality of solder balls 35 to be fully arranged on the whole of the second surface 31b of the package substrate 31, and the plurality of solder balls 35 may be partially arranged.

In addition, fixing of the controller chip 32 to the package substrate 31, fixing of the semiconductor memory 42 to the package substrate 41, and fixing between the plurality of the semiconductor memories 42 are performed by mount films 38 and 48.

In addition, as illustrated in FIG. 4, the controller 13 according to the present embodiment has a substantially rectangular shape, and includes a first edge 13a in a lateral direction, a second edge 13b opposite to the first edge 13a, a third edge 13c in a longitudinal direction, and a fourth edge 13d opposite to the third edge 13c. The second edge 13b is positioned on the NAND memory 12 that is mounted on the substrate 11 and adjacent to the controller 13, and the first edge 13a is positioned on the connector section 21 included in the substrate 11.

In addition, the solder balls 45 described above include solder balls 45a that are arranged on a side of the first edge 13a of the controller 13, and solder balls 45b that are arranged on a side of the second edge 13b. In addition, the solder balls 35 includes solder balls 35a that are positioned on a side of the controller 13 and solder balls 35b that are positioned on a side opposite to the solder balls 35a.

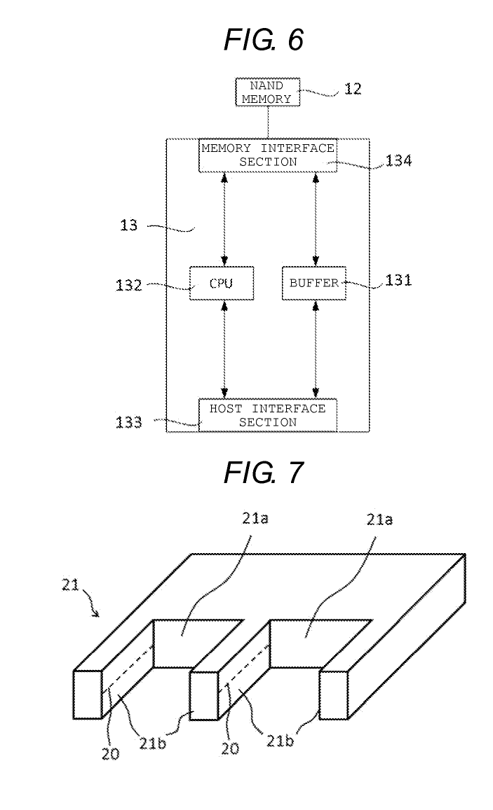

FIG. 6 illustrates an example of a system configuration of the controller 13. As illustrated in FIG. 6, the controller 13 includes a buffer 131, a central processing unit (CPU) 132, a host interface section 133, and a memory interface section 134.

The buffer 131 temporarily stores a certain amount of data, when data that is transferred from the host device 201 is written to the NAND memory 12, or temporarily stores a certain amount of data, when data that is read from the NAND memory 12 is transferred to the host device 201.

The CPU 132 controls the entire semiconductor device 1. For example, the CPU 132 receives a write command, a read command, and an erasure command from the host device 201 and access a corresponding area of the NAND memory 12, or controls data transfer processing via the buffer 131.

The host interface section 133 is positioned between the connector section 21 of the substrate 11 and the CPU 132, and between the connector section 21 and the buffer 131. The host interface section 133 performs interface processing between the controller 13 and the host device 201. For example, a PCIe high-speed signal is transferred between the host interface section 133 and the host device 201.

In addition, the host interface section 133 is arranged at the connector section 21 of the substrate 11, that is, so as to be offset towards the first edge 13a of the controller 13. As a result, it is possible to shorten the wires between host interface section 133 and the connector section 21 of the substrate 11.

For example, if the host interface section 133 is arranged apart from the connector section 21, that is, so as to be offset towards the second edge 13b, in the controller 13, a wiring distance is also extended by a length in a longitudinal direction of a controller chip, as may also be seen from FIG. 4. Since the wires are lengthened, a parasitic capacitance, a parasitic resistance, and a parasitic inductance increase, and it is difficult to maintain a characteristic impedance of signal wires. In addition, it may cause signal delay.

From the above viewpoint, it would be preferable that the host interface section 133 is arranged so as to be offset towards a first edge 13a of the controller 13, and for example, if a command is transferred from a host device, the connector section 21 receives a signal from the host device 201, and performs signal communication with the host interface section 133 via the solder ball 45a from patterned wires of the substrate 11. According to this configuration, operational stability of the semiconductor device 1 can be increased.

In addition, it is preferable that an electronic component is not disposed between the host interface section 133 and the connector section 21 of the substrate 11.

As described above, if a wiring distance between the host interface section 133 and the connector section 21 is long, impedance of a signal wire may not be stabilized, and a signal may be delayed. Thus, it would not be preferable that an electronic component is disposed between the host interface section 133 and the connector section 21, in order to form a wire that connects the host interface section 133 to the connector section 21 in a shortest distance, that is, to form in a straight line.

In addition, an electronic component, such as the power supply circuit 17 or the DRAM 14, may cause noise at the time of operation. As the electronic component is not disposed between the host interface section 133 and the connector section 21, that signals transferred between the host interface section 133 and the connector section 21 are less likely to contain noise, and thus, the operational stability of the semiconductor device 1 may be increased.

The memory interface section 134 is positioned between the NAND memory 12 and the CPU 132 and between the NAND memory 12 and the buffer 131. The memory interface section 134 performs interface processing between the controller 13 and the NAND memory 12.

In the present embodiment, the memory interface section 134 is arranged in a side opposite to the connector section 21 of the substrate 11, that is, arranged so as to be offset towards the second edge 13b of the controller 13. As a result, it is possible to shorten a wiring distance between the memory interface section 134 and the NAND memory 12.

A signal from the controller 13 is transferred to the patterned wires of the substrate 11 via the solder ball 45b, and is transferred to the semiconductor memory 32 from the solder ball 35a. According to this configuration, a wiring distance is shortened, and operational stability of the semiconductor device 1 is increased.

In addition, it is preferable that the power supply circuit 17, the DRAM 14, or the like is not disposed also between the memory interface section 134 of the controller 13 and the NAND memory 12 on the substrate 11. This is for reducing the possibility that signals transferred between the memory interface section 134 and the connector section 21 contains noise, and for increasing operational stability of the semiconductor device 1.

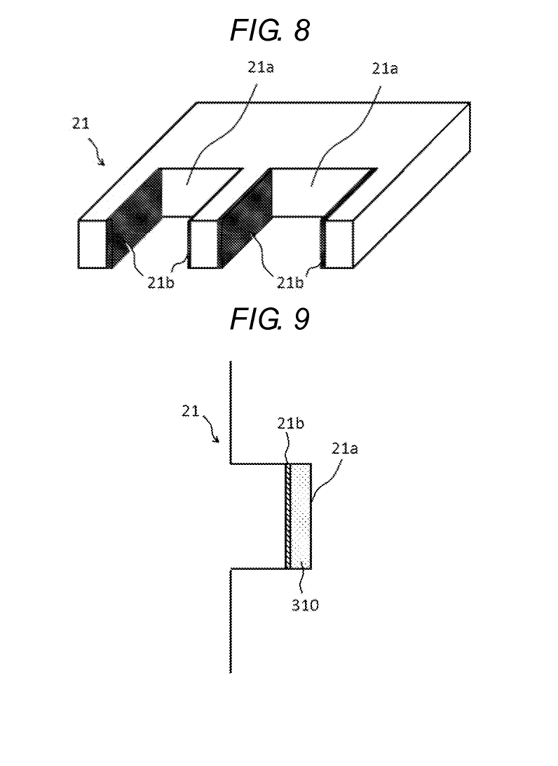

FIG. 7 and FIG. 8 are perspective views of the connector sections 21 in the semiconductor device 1 according to the present embodiment. As illustrated in FIG. 7, the connector section 21 in the present embodiment includes, for example, a plurality of first concave curve sections 21a. In addition, the connector section 21 has a structure in which a surface of a conductive layer 20 of the substrate 11 is partially exposed, and a plurality of first plating sections 21b is provided on the surface of the exposed conductive layers 20 in side surfaces of the first concave curve sections 21a, as illustrate in FIG. 8. The first plating sections 21b are plated with, for example, gold, but are not limited to this. In addition, the gold plating is not necessarily required, and the conductive layer 20 may be in an exposed state. Furthermore, the conductive layer 20 exposed on the side surface of the first concave curve section 21a may not be a layer shape, and a portion that is electrically connected to the conductive layer 20 may be exposed on the side surface, in a state like a signal line, for example.

In addition, the connector section 21 may have a structure in which an elastic material 310 is included, between the first plating section (first metal section) 21b and the side surface of the substrate 11, in a state of being electrically connected to the conductive layer 20. In addition, for example, rubber, urethane, silicon elastomer, or the like is used for the elastic material 310.

FIG. 9 illustrates a top sectional view of the connector section 21, when an elastic material is disposed between the first metal section 21b and the substrate 11. In addition, in FIG. 9, the first metal section 21b is provided at a position only in a lateral direction of the substrate 11, in the first concave curve section 21a, but is not limited to this.

In addition, as described above, the first metal section 21b is required to be electrically connected to the conductive layer 20, but, for example, a signal line may be electrically connected via the center of the elastic material 310, and the exposed conductive layer 20 and the first metal section 21b may be in contact with each other, in a portion which is not covered with the elastic material 310.

In this case, the interface section 221 is pressed by the connector section 21 according to the elastic force of the elastic material 310, whereby stability of electric connection is increased.

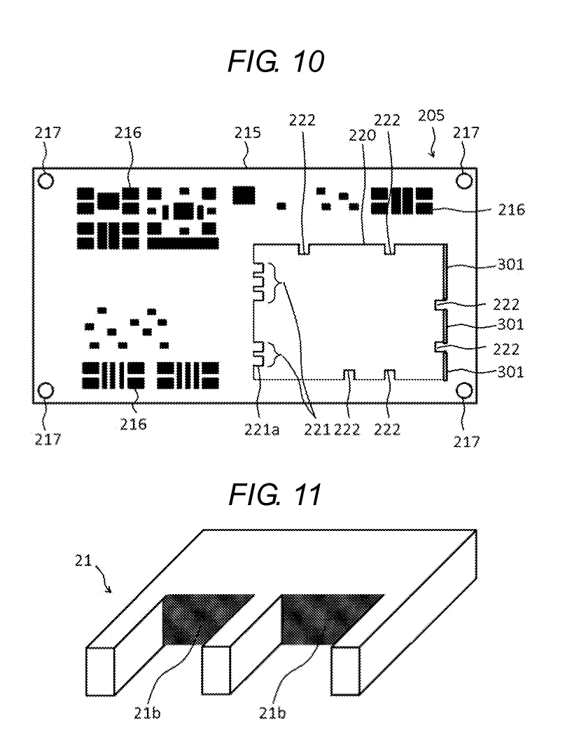

FIG. 10 is a plan view of the main board 205 mounted on the host device 201 to which the semiconductor device 1 is connected. The main board 205 includes a substrate 215, and the substrate 215 includes a first surface 215a and a second surface 215b opposite to the first surface 215a. In addition, the substrate 215 is a multi-layer wiring plate, and includes a conductive layer 225 in the same manner as the substrate 11. In the present disclosure, a surface other than the first surface 215a and the second surface 215b among the surfaces that configures the substrate 215 is defined as a “side surface.”

A penetration section 220 that is hollowed out from the first surface 215a to the second surface 215b of the substrate 215 is provided in the main board 205, and the main board 205 includes the interface section 221 that is electrically connected to the semiconductor device 1. A surface that configures the penetration section 220 in the substrate 215 is referred to as a “side surface” by the definition described above.

The penetration section 220 has the same shape as the shape of the semiconductor device 1, as illustrated in FIG. 10. That is, the main board 205 includes a plurality of first convex curve sections 221a that respectively meshes the plurality of first concave curve sections of the connector section 21 and a plurality of second convex curve sections 222 that respectively mesh the plurality of second concave curve sections 22, in such a manner that the penetration section 220 has the same shape as the substrate 11.

The interface section 221 includes the plurality of first convex curve sections 221a as described above. In addition, the interface section 221 has a structure in which a surface of the conductive layer 225 of the substrate 215 is partially exposed, and a plurality of second plating sections 221b is formed on the surface of the exposed conductive layers 225 in side surfaces of the first convex curve sections 221a, in the same manner as in a case of the substrate 11. The second plating sections 221b are also plated with, for example, gold in the same manner as the first plating sections 21b, but are not limited to this. The first concave curve sections 21a on which plating is performed are meshed with and in contact with the first convex curve sections 221a on which plating is performed in the same manner, whereby the semiconductor device 1 is electrically connected to the host device 201. Here, the gold plating may not be necessary, and the conductive layer 225 may be exposed and in contact with the connector section 21.

In addition, the interface section 221 may have a structure in which an elastic material 310, such as rubber or urethane is included between the second plating section (second metal section) 221b and the side surface of the substrate 215, in a state of being electrically connected to the conductive layer 225, in the same manner as in the connector section 21 described above.

In this case, the connector section 21 is pressed by the interface section 221 according to the elastic force of the elastic material 310, whereby stability of electric connection is increased.

In addition, in the present embodiment, the first two plating sections 21b are provided in one of the first concave curve section 21a. Here, it is preferable that the first two plating sections 21b that face each other conducts the same type of signals, that is, it is preferable that signals conducted in one concave curve section are one type. In this case, one of the first two plating sections 21b that face each other may be in contact with the second plating section 221b of the first convex curve section 221a that is provided on the substrate 215 of the main board 205. As a result, stability of an electrical connection may be increased.

In addition, the first plating section 21b may not be provided on the side surface of the first concave curve section 21a, and may be arranged in the first concave curve section 21a in a lateral direction of the substrate 11 as illustrated in FIG. 11, for example. In this case, a pressing section 301 is provided on a side opposite to the interface section 221, in the penetration section 220 of the substrate 215, whereby it is possible to increase stability of an electrical connection between the substrate 11 and the main board 205. In addition, the first plating section 21b may be provided so as to cover the entire first concave curve section. In this case, the first plating sections 21b are provided on three surfaces that form the first concave curve section 21a, any one surface of those may be in contact with the second plating section 221b of the first convex curve section 221a. As a result, stability of an electrical connection can be further increased. In each case, the second plating section 221b is provided in the first convex curve section 221a, so as to be in contact with the first plating section 21b that is provided in the first concave curve section 21a.

Here, an elastic material such as rubber is used for the pressing section 301. By providing the elastic material in a thickness direction of the substrate 215, the substrate 11 (semiconductor device 1) that is fit into the main board 205 is always in a state of being pressed against the interface section 221, and a more stable electrical contact may be made. The pressing section 301 is not limited to an elastic material formed of rubber and may be a mechanism formed of a spring. In addition, the pressing section 301 need not to be necessarily provided on the substrate 215, and may be provided on the second edge 11d of the substrate 11.

In addition, as illustrated in FIG. 4, the substrate 11 includes a plurality of screw holes 11e. The substrate 11 is also screwed to the second fixing sections 231 of the housing 202 in the same manner as in the main board 205, whereby the semiconductor device 1 may be fixed in the thickness direction of the substrate 11. Furthermore, the plurality of the first convex curve sections 221a and the plurality of the second convex curve sections 221b of the main board 205 are respectively meshed with the plurality of the first concave curve sections 21a and the plurality of the second concave curve sections 22 of the substrate 11, respectively, whereby the semiconductor device 1 is also fixed in the surface direction of the substrate 11. When the semiconductor device 1 is fixed to the second fixing sections 231, it is possible to perform more stable assembly work.

In the present embodiment, the semiconductor device 1 is fixed to the second fixing sections 231, in a state in which the main board 205 is fixed to the first fixing sections 230, and at the same time the connector section 21 and the interface section 221 are electrically connected to each other.

In addition, in the present embodiment, fixing of the semiconductor device 1 and the main board 205 need not to be necessarily performed using screws, and for example, may be performed by pinning or using a material such as an adhesive. The mechanisms or shapes of the first fixing sections 230 and the second fixing sections 231 may be changed in accordance with a fixing method.

In each case, height dimension of the protrusions of the first fixing sections 230 and the second fixing sections 231 is uniform, whereby the connector section 21 and the interface section 221 according to the fixing of the semiconductor device 1 are in contact with each other, and are electrically connected. In addition, in the present embodiment, the first concave curve section 21a and the first convex curve section 221a may not be necessary, and the connector section 21 and the interface section 221 may have configurations in which the plurality of the first plating section 21b and the plurality of second plating section 221b are respectively provided on the side surfaces of the substrate 11 and the side surfaces of the substrate 215.

In addition, in the present embodiment, the second concave curve section 22 and the second convex curve section 222 may not be necessary. When the second concave curve section 22 and the second convex curve section 222 are provided, it is possible to perform more stable assembly work when the above-described semiconductor device 1 is screwed.

Furthermore, in the present embodiment, convex curve sections may be provided on the substrate 11, and concave curve sections may be provided on the substrate 215. Alternatively, concave curve sections and convex curve sections may be provided on both of the substrate 11 and the substrate 215.

Here, it is assumed that a semiconductor device is not fit into a main board, and the semiconductor device is inserted into a slot that is provided on a surface of the main board. In this case, by inserting the semiconductor device into the slot that is provided in the main board, the semiconductor device and a host device are electrically connected to each other. In this case, the semiconductor device and the main board that are inserted into the slot are arranged so as to be arranged substantially in parallel. When a semiconductor package is disposed in a host device, an mounting space having a height of the semiconductor package that is disposed in the semiconductor device may be required, as illustrated in, for example, FIG. 5.

In addition, an embedded multimedia card (eMMC) in which a NAND memory and a controller are incorporated into one package may be disposed in a main board. In this case, the host device may be thinner, but the operation speed of the eMMC may not be as fast as that of an SSD, and exchange of components may be extremely difficult.

To the contrary, the present embodiment has a structure in which the semiconductor device 1 is fit into the penetration section 220 of the main board 205. According to this configuration, the main board 205 and the substrate 11 are provided on substantially the same plane. Thus, the semiconductor device 1 is located in a space required for mounting the main board 205, in the thickness direction of the host device 201, whereby the host device 201 may be thinner.

Furthermore, in the present embodiment, the semiconductor device 1 and the main board 205 do not overlap each other. For this reason, it is possible to suppress heat generated from a component (for example, controller 13) on the semiconductor device 1 from being conducted to the main board 205 through the air.

In addition, the height of the semiconductor package, such as the NAND memory 12 or the controller 13, which is disposed on the substrate 11, is also substantially the same as that of a plurality of circuit components 216 on the main board 205. As a result, a mounting space need not to be increased by taking into account an amount of protrusion of a component that is disposed on the substrate 11, a space for the main board 205 and the semiconductor device 1 can be saved, and the host device 201 may be formed in a thin shape.

Furthermore, the semiconductor device 1 according to the present embodiment is a device of single-sided mounting. As a protruding electronic component is not provided on a rear surface, a mounting space of the host device 201 in which the semiconductor device 1 is disposed is decreased, and accordingly the host device 201 may be formed in a thin shape.

In addition, as described above, even if an electronic component of the semiconductor device 1 is disposed on the substrate 215 which directly configures the main board 205, the host device 201 may be formed in a thin shape. However, in the present embodiment, the semiconductor device 1 can be easily removed. Thus, also from a viewpoint of a performance test at the time of failure of components, or easiness of chip exchange, the present embodiment would be superior to a case in which the components, such as the NAND memory 12 or the controller 13, are directly disposed on the substrate 215.

In addition, the present embodiment does not have a structure in which the semiconductor device 1 is inserted into a slot. Thus, a connection section that connects the main board 205 to the semiconductor device 1 need not be configured along only the first edge 11a of the substrate 11, and for example, may be provided in two edges adjacent to each other. In this case, it is possible to suppress concentration of wires in the periphery of the connector section 21, and degree of freedom of routing or the like of the wires in the semiconductor device 1 is increased. For this reason, electronic components, such as the NAND memory 12, the controller 13, and the DRAM 14 may also be more compactly arranged, and thus the semiconductor device 1 may also be miniaturized.

Furthermore, in the same manner as in the main board 205, wires through which the semiconductor device 1 and the host device 201 performs data communication need not be concentrated to one interface section 221, and routing of wires or component arrangement in the main board 205 can be more freely designed.

In addition, in the present embodiment, the connector section 21 and the interface section 221 do not include components to connect each other and are provided on the side surfaces of the substrate 11 and the substrate 215. According to this configuration, not only the number of components that are used for the host device 201 is reduced, but also a space for disposing components and wires according to the components need not be considered. As a result, the semiconductor device 1 and the main board 205 are miniaturized, and degree of design freedom is increased.

Furthermore, in the present embodiment, the semiconductor device 1 is fixed to the housing 202 and at the same time an electrical connection is established. Thus, it is not necessary to take a space into account, when designing, in order to perform an electrical connection, for example, to perform insertion and removal, and this also leads to a miniaturization of the host device 201.

The first embodiment is described as above, but the embodiment of the semiconductor device 1 is not limited to the first embodiment. Next, a semiconductor device according to a second embodiment will be described. The same symbols or reference numerals will be used for elements having the same or similar function as that of the first embodiment, and description thereof will be omitted. In addition, elements except for the elements described below are the same as those of the first embodiment.

### Second Embodiment

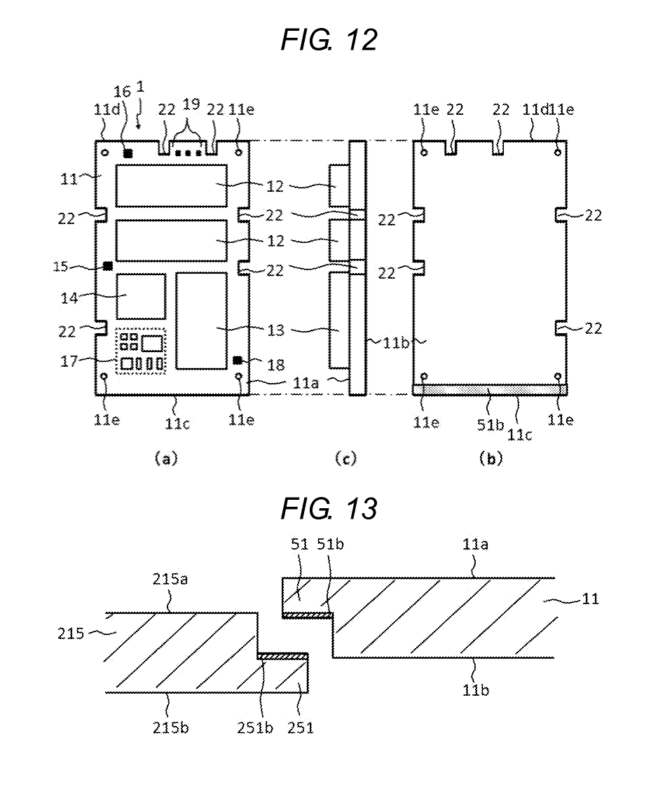

The semiconductor device 1 according to a second embodiment is illustrated in FIG. 12. In FIG. 12, (a) is a plan view of a top surface, (b) is a plan view of a bottom surface, and (c) is a side view of a side surface. In addition, FIG. 13 is a cross-sectional view of the semiconductor device 1 and the main board 205 according to the second embodiment.

The connector section 51 according to the present embodiment includes a stage 51a, as illustrated in FIG. 12 and FIG. 13. Since the substrate 11 is a multi-layer substrate, the number of layers that configures the connector section 51 is smaller than that of the other sections. That is, since the connector section 51 is processed in a thin shape, the stage 51a illustrated in FIG. 13 may be formed.

In addition, in the stage 51a of the substrate 11, a first plating section (first metal section) 51b is provided on a surface that is substantially parallel with the first surface 11a of the substrate 11, and the first plating section 51b is electrically connected to the conductive layer 20 of the substrate 11 in the same manner as in the first embodiment.

In addition, the main board 205 includes an interface section 251. The interface section 251 includes a stage 251a as illustrated in FIG. 13. In the same manner as in the substrate 11, the substrate 215 that configures the main board 205 is also a multi-layer substrate. Thus, by thinning a portion in the same manner as in the substrate 11 according to the present embodiment, the stage 251a may be formed.

Furthermore, when the semiconductor device 1 is fit into the penetration section 220, a second plating section (second metal section) 251b is provided on a surface that is in contact with the first plating section 51b, in the stage 251a. The plating sections are in contact with each other, whereby the semiconductor device 1 and the host device 201 are electrically connected to each other.

In the same manner as in the main board 205, the substrate 11 is also screwed to the housing 202, whereby the semiconductor device 1 may be fixed in the thickness direction of the substrate 11. Furthermore, the stage 251a of the main board 205 and the plurality of the second convex curve sections 221b are respectively meshed with the stage 51a of the substrate 11 and the plurality of the second concave curve sections 22, whereby the semiconductor device 1 is also fixed in a surface direction of the substrate 11.

In addition, screw holes are provided in the stages 51b and 251b and the substrates 11 and 215 may be screwed to the housing 202. In this case, the first plating section 51b is pressed toward the second plating section 251b by the screw, whereby an electrical connection may be stable. It is preferable that screws used in this case are made of an insulating material such as plastic.

In addition, the second concave curve section 22 and the second convex curve section 222 are provided in the substrate 11 and the main board 205 in the present embodiment, in the same manner as in the first embodiment. However, a method of fixing the semiconductor device 1 is not limited to this, and for example, the semiconductor device 1 may have the same structure as that of the stages 51a and 251a provided in the connector section 51 and the interface section 251, respectively.

In addition, also in the present embodiment, an elastic material may be disposed between the first metal section 51b and the substrate 11, in the same manner as in the first embodiment. In the present embodiment, a screw direction and a pressing direction of the elastic material substantially coincide with each other, whereby an electrical connection may be more stable.

The present embodiment also has a configuration in which the semiconductor device 1 is positioned on substantially the same plane as the main board 205, a space in which the semiconductor device 1 and the main board 205 are disposed may be reduced, and the host device 201 may be thinned.

In addition, the present embodiment also describes an example in which the semiconductor device 1 is fit into the penetration section 220 of the substrate 215, but is not limited to this. In addition, the semiconductor device 1 is fixed to the second fixing sections 231 also in the present embodiment, whereby the semiconductor device 1 and the main board 205 are electrically connected to each other.

### Third Embodiment

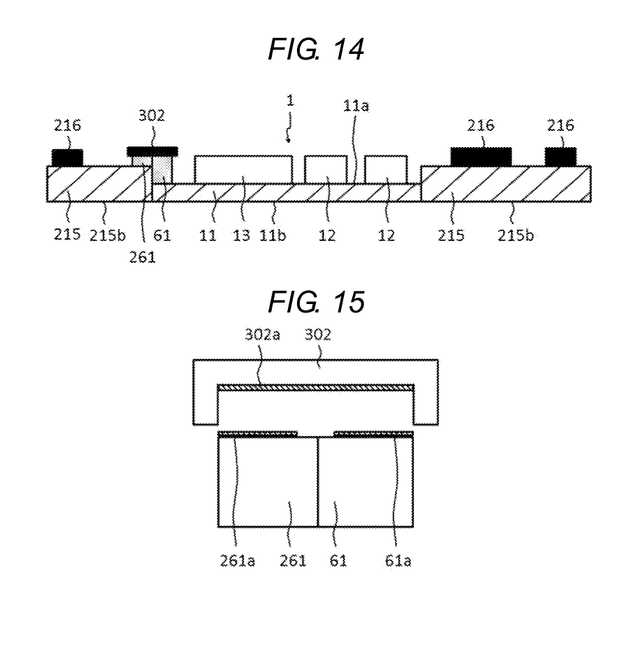

A sectional side view of the semiconductor device 1 and the main board 205 according to a third embodiment is illustrated in FIG. 14. A connector section need not to be necessarily provided on the side surface of the substrate 11 as described in the first and second embodiments, and may be disposed on the first surface 11a of the substrate 11 as a connector component. In the same manner, an interface section provided in the main board 205 may also be disposed on the mounting surface 215a of the substrate 215.

In the present embodiment, a connector section 61 and an interface section 261 are disposed together on the mounting surface 215a as a connector component. The connector section 61 and the interface section 261 respectively include a metal section 61a and a metal section 261a on an upper surface of a component (a surface on a side opposite to the mounting surface 215a). In addition, as illustrated in FIG. 14, the connector section 61 and the interface section 261 are covered with a cover 302.

A sectional view of the connector section 61, the interface section 261, and the cover 302 is illustrated in FIG. 15. As illustrated in FIG. 15, a conductive section 302a is provided in an inner side of the cover 302, and the metal section 61a provided in the connector section 61 and the metal section 261a provided in the interface section 261 are electrically connected to each other via the conductive section 302a provided in the cover 302.

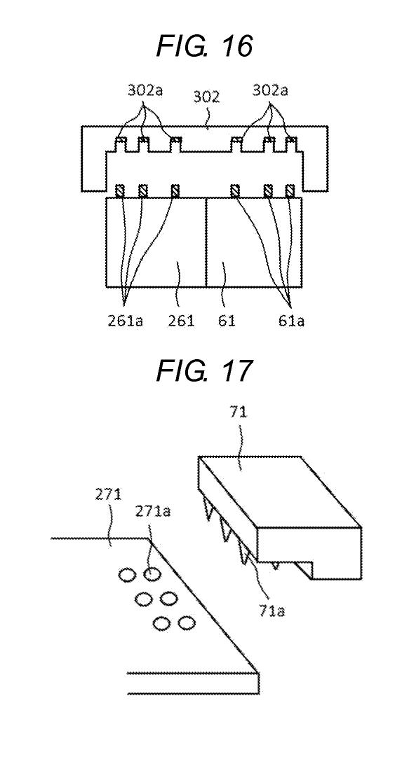

In the present embodiment, the metal section 61a and the metal section 261a include, for example, multiple pieces and may be respectively connected by a plurality of the conductive sections 302a that is provided so as to connect each other. As illustrated in FIG. 16, when the connector section 61 and the interface section 261 are covered with the cover 302, the metal sections 61a and 261a of a male terminal shape are inserted into the conductive sections 302a of a female terminal shape, and may be electrically and respectively connected by a conductive layer (not illustrated) provided inside the cover 302.

In addition, plating sections of the connector section 61 and the interface section 261 according to the present embodiment may be provided on side surfaces thereof in a state in which the plating sections are in contact with each other. In this case, the semiconductor device 1 is fixed to the second fixing sections 231, whereby the connector section 61 and the interface section 261 are in contact with each other, and are electrically connected to each other. In addition, the connector section 61 and the interface section 261 are fixed to each other in a state of being pressed by the cover 302, and stability of an electrical connection is maintained.

In addition, in the present embodiment, the connection section protrudes on each of the mounting surface sides with respect to the substrate 11 and the substrate 215, differently from the connector section and the interface section according to the first and second embodiments. However, as illustrated in FIG. 14, since various electronic components including the NAND memory 12 are disposed on the substrate 11 and the substrate 215, if the connector section 61 and the interface section 261 are provided within a range of a height that is formed by protrusion of the various electronic components, the breadth of a mounting space need not be changed, and in the same manner as in the first and second embodiments, the host device 201 may be formed in a thin shape.

### Fourth Embodiment

A connector section 71 of the semiconductor device 1 and an interface section 271 of the main board 205, according to a fourth embodiment are illustrated in FIG. 17.

As illustrated in FIG. 17, a connector section 71 that is provided in the semiconductor device 1 includes a plurality of male terminals 71a. In addition, an interface section 271 that is provided on the mounting surface 215a of the substrate 215 includes a plurality of female terminals 271a that includes the same number of pieces as the male terminals 71a, and an electrical connection is established by the male terminals 71a being inserted into the female terminals 271a.

Since an electrical connection according to the present embodiment is made by inserting terminals of a pin shape into each other, the semiconductor device 1 according to the present embodiment has a more electrically stable structure than a structure in which conductive materials (for example, plating materials) are merely in contact with each other.

Furthermore, the connector section 71 and the interface section 271 in the present embodiment respectively have structures in which the mounting surface sides of the substrate 11 and the substrate 215 protrude, but as illustrated above, various electronic components including the NAND memory 12 are disposed on the substrate 11 and the substrate 215. Thus, if the connector section 71 and the interface section 271 are provided within a range of a height that is formed by protrusion of the various electronic components, the breadth of an mounting space need not be changed, and as a result, the host device 201 may be formed in a thin shape.

### Fifth Embodiment

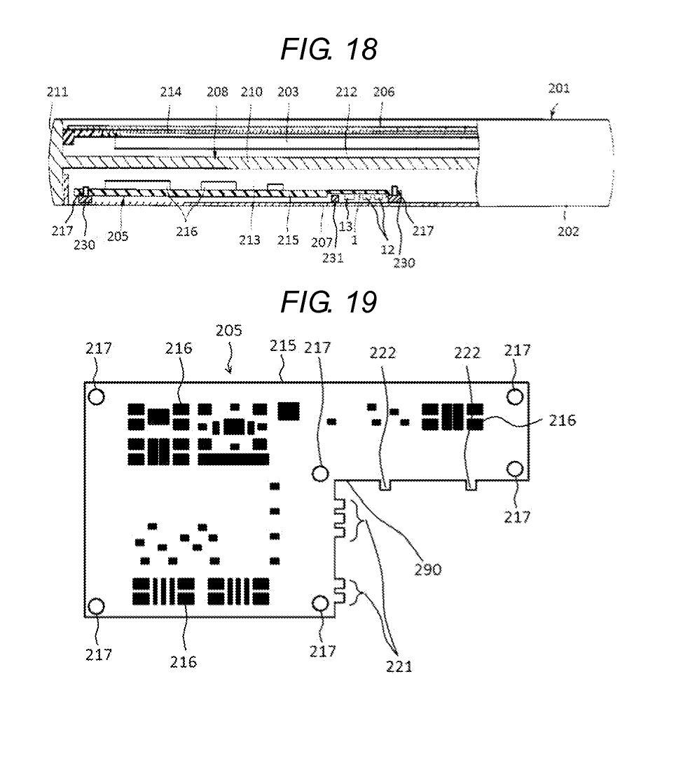

FIG. 18 illustrates a semiconductor device 1 according to a fifth embodiment, which is disposed in a tablet type portable computer 201. In the fifth embodiment, the mounting surface 11a of the substrate 11 is positioned on a side opposite to the mounting surface 215a of the substrate 215 of the main board 205. Thus, in the semiconductor device 1 according to the present embodiment, a protruded component faces a side opposite to a display module.

In the configuration described above, the semiconductor device 1 may be less subjected to the heat generated in the display module, and the operation stability of the semiconductor device 1 may be increased. In addition, since the controller 13 and the housing 202 of the tablet type portable computer 201 are separated from each other, the heat emitted from the controller 13 is suppressed from being diffused to a surface of the tablet type portable computer 201, and it is possible to prevent surface temperature of the tablet type portable computer 201 from increasing. For this reason, a user can safely use the tablet type portable computer 201, and it is possible to improve user convenience.

In addition, the substrate 11 and the substrate 215 are positioned on substantially the same plane, also in the present embodiment. Thus, the semiconductor device 1 is accommodated in a space required for mounting the main board 205, in the thickness direction of the tablet type portable computer 201, whereby the tablet type portable computer 201 may be formed in a thin shape.

In addition, a connection section that connects a connector section to an interface section in the present embodiment may have one of the configurations described in the first to fifth embodiments.

### Sixth Embodiment

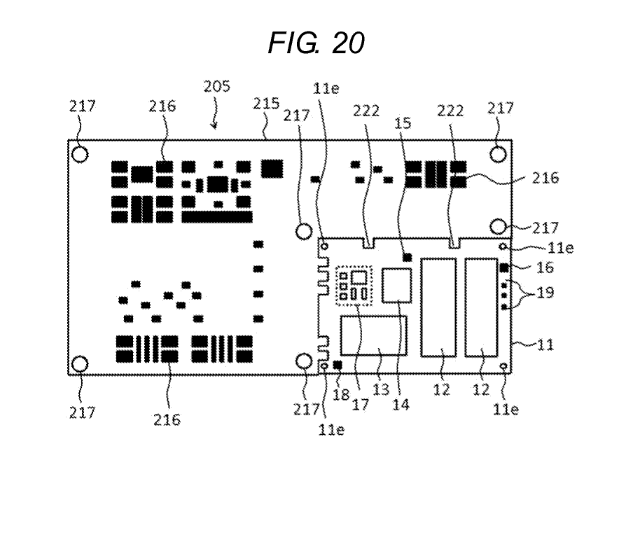

The main board 205 according to a sixth embodiment is illustrated in FIG. 19. As illustrated in FIG. 19, a notch section 290 is provided in a substrate 216 of a substantially rectangular shape in the present embodiment. The semiconductor device 1 is disposed in a position of the notch section 290 as illustrated in FIG. 20.

In addition, a connection section that connects a connector section to an interface section in the present embodiment may have one of the configurations described in the first to fifth embodiments. The connector section 21 and the interface section 221 that are described in the first embodiment are illustrated in FIG. 19 and FIG. 20.

Since the substrate 11 and the substrate 215 are in parallel on substantially the same plane, the semiconductor device 1 is mounted in a space required for disposing the main board 205, in the thickness direction of the host device 201, whereby the host device 201 may be formed in a thin shape.

In addition, the notch section 290 is provided in the present embodiment, but this configuration may not be necessary. The substrate 11 and the substrate 215 on which components are disposed may be respectively fixed in parallel only to the first fixing section 230 and the second fixing section 231. Also in this case, height dimension of the protrusion sections of the first fixing sections 230 and the second fixing sections 231 is uniform, whereby the host device 201 may be formed in a thin shape. According to the fixing of the semiconductor device 1, the semiconductor device 1 and the main board 205 are electrically connected to each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus, comprising:
a housing;
a first circuit board including a first engaging portion configured to fix the first circuit board to the housing, and a first terminal; and
a second circuit board including a second engaging portion configured to fix the second circuit board to the housing, and a second terminal electrically connected to the first terminal.

2. The electronic apparatus according to claim 1, wherein
the first terminal is formed on a side surface of the first circuit board,
the second terminal is formed on a side surface of the second circuit board, and
the first and second terminals are coupled to each other.

3. The electronic apparatus according to claim 2, wherein
the first terminal is located at a protrusive portion formed on the side surface of the first circuit board, and
the second terminal is located at a recessed portion formed on the side surface of the second circuit board.

4. The electronic apparatus according to claim 3, wherein
the first and second terminals are coupled to each when the protrusive portion is fit in the recessed portion.

5. The electronic apparatus according to claim 2, wherein
at least one of the first and second terminals includes an elastic layer that is deformed when the first terminal is coupled to the second terminal.

6. The electronic apparatus according to claim 1, wherein
the first circuit board includes an interface unit configured to transmit a read signal and a write signal to the second circuit board, and
the second circuit board includes a semiconductor memory unit and a control unit configured to control the semiconductor memory unit to read and write data in accordance with the read signal and the write signal, respectively.

7. The electronic apparatus according to claim 1, wherein
one of the first and second terminals is formed at a portion of the corresponding circuit board recessed from an upper surface thereof, and
the other one of the first and second terminals is formed at a portion of the corresponding board recessed from a lower surface thereof.

8. The electronic apparatus according to claim 1, wherein
one of the first and second terminals is formed in a hole extending from an upper surface of the corresponding circuit board, and
the other one of the first and second terminal is a protrusion formed on the corresponding circuit board and fit in the hole.

9. The electronic apparatus according to claim 1, wherein
the first terminal is formed on an upper surface of the first circuit board,
the second terminal is formed on an upper surface of the second circuit board, and
the first and second terminals are electrically connected with a connecting member covering the first and second terminals.

10. The electronic apparatus according to claim 9, wherein
the first terminal includes a plurality of protrusions formed on the upper surface of the first circuit board,
the second terminal includes a plurality of protrusions formed on the upper surface of the second circuit board, and
the connecting member includes a plurality of recessed portions engaged with the protrusions of the first and second terminals.

11. The electronic apparatus according to claim 1, wherein
the first circuit board includes an opening, and the second circuit board is fit in the opening.

12. The electronic apparatus according to claim 1, wherein
the first circuit board includes a notched portion on an edge thereof, and the second circuit board is fit in the notched portion.

13. An electronic apparatus, comprising:
a first circuit board including an interface unit disposed thereon and configured to transmit a read signal and a write signal, and a first terminal; and
a second circuit board including a semiconductor memory unit and a control unit configured to control the semiconductor memory unit to read and write data, which are disposed on a surface thereof, and a second terminal coupled to and electrically connected with the first terminal.

14. The electronic apparatus according to claim 13, wherein
the first terminal is formed on a side surface of the first circuit board, and
the second terminal is formed on a side surface of the second circuit board.

15. The electronic apparatus according to claim 14, wherein
the first terminal is located at a protrusive portion formed on the side surface of the first circuit board, and
the second terminal is located at a recessed portion formed on the side surface of the second circuit board.

16. The electronic apparatus according to claim 15, wherein
the first and second terminals are coupled when the protrusive portion is fit in the recessed portion.

17. The electronic apparatus according to claim 13, wherein
at least one of the first and second terminals includes an elastic layer that is deformed when the first terminal is coupled to the second terminal.

18. The electronic apparatus according to claim 13, wherein
the first circuit board includes an opening, and the second circuit board is fit in the opening.

19. The electronic apparatus according to claim 13, wherein
the first circuit board includes a notched portion on an edge thereof, and the second circuit board is fit in the notched portion.

20. The electronic apparatus according to claim 13, wherein
the first circuit board is a part of a host device.
